(19) United States
(12) Patent Application Publication
(10) Pub. No.: US 2010/0325519 A1
(43) Pub. Date: Dec. 23, 2010

(54) CRC For Error Correction

(75) Inventor: James M. Lyon, Redmond, WA (US)

Correspondence Address: MICROSOFT CORPORATION, ONE MICROSOFT WAY, REDMOND, WA, 98052, US

(73) Assignee: Microsoft Corporation, Redmond, WA (US)

(21) Appl. No.: 12/486,732

(22) Filed: Jun. 17, 2009

(51) Int. Cl. H03M 13/09; G06F 11/08; G06F 11/10

(52) U.S. Cl. 714/758; 714/E11.032; 714/E11.031

(57) ABSTRACT

A cyclic redundancy check (CRC) or other function may be used as an error correction mechanism by analyzing CRC results against a table of CRC results for potential flipped bits. From the table, an incorrect bit may be identified and corrected. Two or more bits may be identified and corrected by testing the XOR of the calculated CRC results with two or more results within the table to identify two or more bits that are incorrect. In one embodiment, data stored on a data storage system may be stored with a calculated CRC for each block of data. When the data is read from the storage system, the CRC function may be used to verify data integrity and to identify one or more bits that are incorrect in the retrieved data.

### BACKGROUND

Error correction is a field of technology that detects the presence of errors in data and attempts to correct the error. In many cases, error correction technologies may fix errors that may have been created due to transmission errors, hardware errors, or other noise in a system.

A data storage system, for example, may store data on several disk drives. In such a system, data may be corrupted when the original data is transmitted to the data storage system, while processing the data for storage, on the storage media itself, and during retrieval and transmission. Magnetic media and other media may lose individual bits of information over time, and electronic noise and other contaminants may cause bits of data to be incorrectly transmitted or processed.

Error correction information may be stored with the raw data and may be used to recreate the original data with some certainty.

### SUMMARY

A cyclic redundancy check (CRC) or other function may be used as an error correction mechanism by analyzing CRC results against a table of CRC results for potential flipped bits. From the table, an incorrect bit may be identified and corrected. Two or more bits may be identified and corrected by testing the XOR of the calculated CRC results with two or more results within the table to identify two or more bits that are incorrect. In one embodiment, data stored on a data storage system may be stored with a calculated CRC for each block of data. When the data is read from the storage system, the CRC function may be used to verify data integrity and to identify one or more bits that are incorrect in the retrieved data.

This Summary is provided to introduce a selection of concepts in a simplified form that are further described below in the Detailed Description. This Summary is not intended to identify key features or essential features of the claimed subject matter, nor is it intended to be used to limit the scope of the claimed subject matter.

### BRIEF DESCRIPTION OF THE DRAWINGS

In the drawings,

FIG. 1 is a diagram illustration of an embodiment showing a storage system with an error detection code being used for error correction.

FIG. 2 is a diagram illustration of an embodiment showing a communication system with an error detection code being used for error correction.

FIG. 3 is a diagram illustration of an embodiment showing the storage of data with error detection codes and metadata.

FIG. 4 is a flowchart illustration of an embodiment showing a method for storing or transmitting data with error detection codes.

FIG. 5 is a flowchart illustration of an embodiment showing a method for error detection and correction.

### DETAILED DESCRIPTION

An error detection mechanism, such as a cyclic redundancy check (CRC) or other error detection code (EDC), may be used to both detect and correct errors in some sets of data. A CRC value may be calculated and appended to data into a block of data that may be stored or transmitted. When the block is received, the block may be evaluated with the CRC function to determine if an error has occurred. If an error has occurred, the CRC value may be used to determine which bit or bits within the block of data are incorrect.

The method of determining an incorrect bit may be used in several applications. In one application, data received over a network or through some data stream may be checked and corrected. In another application, a storage system may add a CRC value to data as it is stored and may check and correct data that is retrieved from storage devices in the system.

Many different functions may be used as error detecting codes (EDC). Examples of EDC include some CRC codes. Any function may work that is linear over the binary field. That is, for every string A and B, F(A xor B)==F(A) xor F(B).

Further, when applied to a string of a specific length, the function results of each string of all zeros with a single bit flip, and each string of all zeros with two bits flipped, yields unique values.

Any function that meets the two previous conditions may be used as an EDC code. Many CRC functions are well known and easy to compute function that satisfies the conditions, such as CRC-64.

Throughout this specification, like reference numbers signify the same elements throughout the description of the figures.

When elements are referred to as being “connected” or “coupled,” the elements can be directly connected or coupled together or one or more intervening elements may also be present. In contrast, when elements are referred to as being “directly connected” or “directly coupled,” there are no intervening elements present.

The subject matter may be embodied as devices, systems, methods, and/or computer program products. Accordingly, some or all of the subject matter may be embodied in hardware and/or in software (including firmware, resident software, micro-code, state machines, gate arrays, etc.) Furthermore, the subject matter may take the form of a computer program product on a computer-usable or computer-readable storage medium having computer-usable or computer-readable program code embodied in the medium for use by or in connection with an instruction execution system. In the context of this document, a computer-usable or computer-readable medium may be any medium that can contain, store, communicate, propagate, or transport the program for use by or in connection with the instruction execution system, apparatus, or device.

The computer-usable or computer-readable medium may be, for example but not limited to, an electronic, magnetic, optical, electromagnetic, infrared, or semiconductor system, apparatus, device, or propagation medium. By way of example, and not limitation, computer readable media may comprise computer storage media and communication media.

Computer storage media includes volatile and nonvolatile, removable and non-removable media implemented in any method or technology for storage of information such as computer readable instructions, data structures, program modules or other data. Computer storage media includes, but is not limited to, RAM, ROM, EEPROM, flash memory or other memory technology, CD-ROM, digital versatile disks (DVD) or other optical storage, magnetic cassettes, magnetic tape, magnetic disk storage or other magnetic storage devices, or any other medium which can be used to store the desired information and which can accessed by an instruction execution system. Note that the computer-usable or computer-readable medium could be paper or another suitable medium upon which the program is printed, as the program can be electronically captured, via, for instance, optical scanning of the paper or other medium, then compiled, interpreted, of otherwise processed in a suitable manner, if necessary, and then stored in a computer memory.

Communication media typically embodies computer readable instructions, data structures, program modules or other data in a modulated data signal such as a carrier wave or other transport mechanism and includes any information delivery media. The term “modulated data signal” means a signal that has one or more of its characteristics set or changed in such a manner as to encode information in the signal. By way of example, and not limitation, communication media includes wired media such as a wired network or direct-wired connection, and wireless media such as acoustic, RF, infrared and other wireless media. Combinations of the any of the above should also be included within the scope of computer readable media.

When the subject matter is embodied in the general context of computer-executable instructions, the embodiment may comprise program modules, executed by one or more systems, computers, or other devices. Generally, program modules include routines, programs, objects, components, resources, data structures, etc. that perform particular tasks or implement particular abstract data types. Typically, the functionality of the program modules may be combined or distributed as desired in various embodiments.

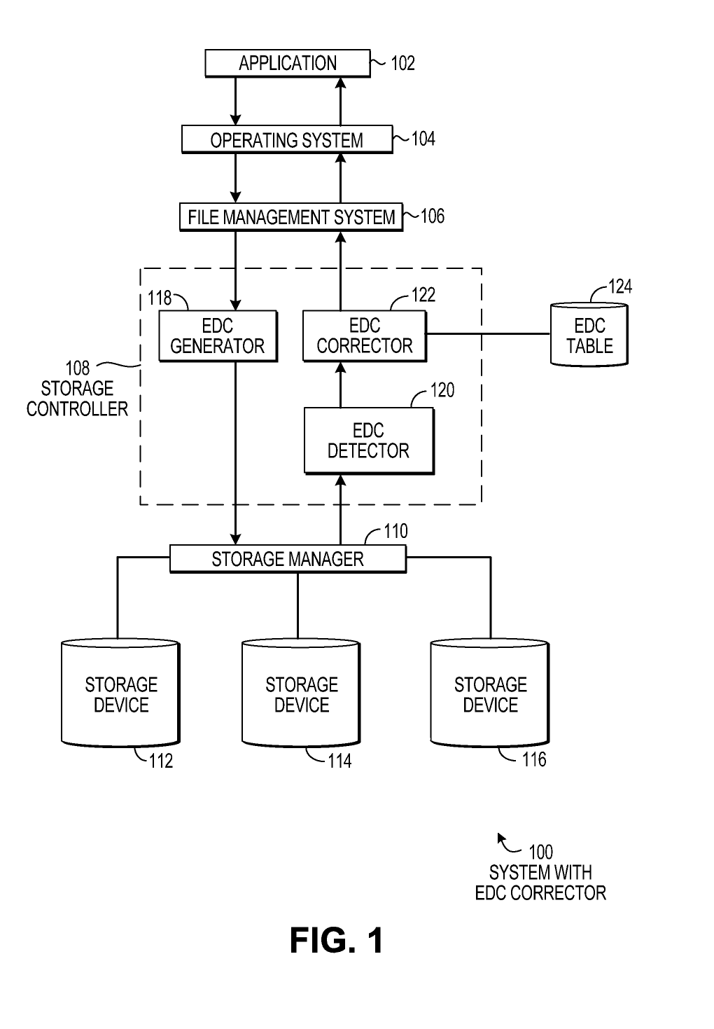

FIG. 1 is a diagram of an embodiment 100 showing a storage system that may be use Error Detection Codes (EDC) for both error detection and error correction. Embodiment 100 is a simplified example of an example of such a system that may be used in a storage system.

The diagram of FIG. 1 illustrates functional components of a system. In some cases, the component may be a hardware component, a software component, or a combination of hardware and software. Some of the components may be application level software, while other components may be operating system level components. In some cases, the connection of one component to another may be a close connection where two or more components are operating on a single hardware platform. In other cases, the connections may be made over network connections spanning long distances. Each embodiment may use different hardware, software, and interconnection architectures to achieve the functions described.

Embodiment 100 is an example of a storage system that may use error detecting codes for both error detection and error correction. The storage system may be a disk based storage system, such as disk storage system used by a personal computer or server computer. In some embodiments, the storage system may represent a Storage Area Network (SAN), Network Attached Storage (NAS), or other system that may provide storage services. The storage system may use solid state storage media, hard disks, tape storage media, optical storage media, or any other storage mechanism.

Embodiment 100 is an example of a system that may use error detecting codes for both error detection and error correction. When information is being stored onto storage devices, an error detection algorithm may be used to generate a checksum or error correcting code, which may be added to the data and stored with the data. When the data and error correcting code are read from the storage media, the data may be processed by the error detection algorithm to detect if an error has occurred in the data.

In many embodiments, the term “checksum” may be used as a shorthand notation for the result of processing data with an error detecting code. The error correcting code result or checksum is usually created such that the error detecting algorithm will result in a zero or other default value when the data with the appended error correcting code are evaluated with the error detecting algorithm.

If an error has occurred in the data, the result may be used to isolate one, two, or more bits within the stored data and correct the incorrect bits.

When a block of data is read from a storage device, the error detecting code function may be performed on the data to determine if the data is corrupted or not. If the computed checksum or EDC result is not the default value, the EDC result may be used to identify which bit or bits are incorrect in the block of data.

In many embodiments, the default value for the EDC result may be all zeros in a binary representation. In other embodiments, the default value may be all ones in a binary representation. Other embodiments may have other default values.

For certain EDC functions performed on a data set of a certain size, the function may be linear over the binary field. That is, for every string A and B, F(A XOR B)==F(A) XOR F(B), and the function results of each string of all zeros with a single bit flip, and each string of all zeros with two bits flipped, yields unique values.

In order to determine if a specific function may be used in a certain application, an EDC table may be computed using that function. An EDC table may be created by establishing a size for a data set. In the example of embodiment 300 provided later in this specification, a data set of 512 bytes is used, which equates to 4096 bits.

The EDC table may be computed by starting with an input string of 4096 bits all set to zero and computing the EDC result. For each bit in the string, a string of all zeros with one bit flipped may be evaluated and the EDC result may be calculated. The table may be 4096 rows long and may contain 4096 EDC results.

A function that may be used as an EDC function may be any function that returns unique results for each row of an EDC table and for which the F(A XOR B)==F(A) XOR F(B) property is true over every value.

If a block of data produces an EDC result that is in the EDC table, the corresponding flipped bit from the EDC table is the single incorrect bit in the block of data. If the EDC result is the XOR of two results in the EDC table, the two bits represented by the two EDC results in the EDC table are incorrect. It also follows that when three bits are incorrect, the EDC results will be the XOR of three of the EDC results in the EDC table, and each of the EDC results will correspond with the incorrect bits.

Embodiment 500, described later in this specification, may illustrate one method that may be used to correct a block of data using the EDC results.

Embodiment 100 illustrates a typical system that may store and retrieve data. An application 102 may interact with an operating system 104 that may have a file management system 106 as a component of the operating system. An application 102 may be a program or group of executable code that operates on a processor to perform a function.

An operating system 104 may be an interface between hardware and applications. An operating system typically manages activities and sharing of resources of a computer system, and may act as a host for applications that are executed on the machine. As a host, an operating system may handle the details of the operation of the hardware, relieving an application from having to manage such details. Many computers, including handheld computers, desktop computers, supercomputers, cellular telephones, and even video game consoles, may use an operating system of some type.

The file management system 106 may provide storage and organization to computer files. The file management system 106 may receive and respond to commands to create and manage files, as well as to write to and read from the files. In many cases, the file management system 106 may provide many complex capabilities such as file access control, managing metadata about the files, transaction processing, and other capabilities. Many different types of file management systems may be created to address specific applications.

A file management system 106 may interact with a storage controller 108 and a storage manager 110 for storing and retrieving data from storage devices 112, 114, and 116. In some embodiments, the storage controller 108 and storage manager 110 may be a peripheral device such as a hard disk controller, RAID controller, or some other device specially designed for performing storage and retrieval operations on storage devices. In some embodiments, some of the functions of the storage controller 108 may be performed in software that may be a component of the file management system 106 or operating system 104.

The storage devices 112, 114, and 116 may be arranged in several different manners. In some embodiments, such as a Redundant Array of Independent Disks (RAID), the storage devices 112, 114, and 116 may be identical devices that are operated in unison. In some RAID configurations, several storage devices may use striping techniques to simultaneously write and read data to the devices in parallel. In such embodiments, the storage manager 110 may have specialized hardware, firmware, or software for performing read and write operations to the storage devices 112, 114, and 116.

In another embodiment, the storage manager 110 may manage several storage devices 112, 114, and 116 as one or more virtual storage devices. A virtual storage device may comprise the storage capacity of several storage devices 112, 114, and 116 as a single storage device to the file management system 106. The example of RAID above is a specialized instance of a virtual storage device. Other embodiments may aggregate several storage devices together where the storage devices may not be identical and may have vastly different storage capacities. In some such embodiments, the storage devices may connect to the storage manager 110 using different types of interfaces that may have different performance characteristics.

In some embodiments, a group of storage devices may contain many virtual storage devices that may be deployed over several storage devices. In some such embodiments, a virtual storage device may have certain data that are stored on multiple storage devices. For example, a virtual file system may have a directory that is marked such that the storage manager 110 may place a copy of the directory information on two or more storage devices 112, 114, or 116 for redundancy of data storage. These examples merely show some examples of the breadth of configurations for storage systems and are not to be considered limiting.

The storage controller 108 may append data to be written with a checksum using an EDC generator 118. The EDC generator may analyze a block of data and generate a checksum or EDC result that may be appended to the data and stored with the data as a block. One process of calculating a checksum or EDC result and appending the result to the data may be found in an example of embodiment 400 described later in this specification. Other methods may also be employed.

When the block of data is retrieved, an EDC detector 120 may perform the EDC function on the block of data to determine if any errors exist in the data. In a typical embodiment, the EDC may calculate a checksum for the entire block of data. When the checksum is a default value, the data may be considered to be correct. In many EDC formulas, it is possible for multiple bit changes to a block of data to yield the default value, however, the possibility of such changes may be miniscule.

If the EDC result is not the default value, the EDC corrector 122 may use an EDC table 124 to attempt to identify which bit or bits are incorrect in the block of data. In some embodiments, the EDC corrector 122 may attempt to correct one or two incorrect bits by searching the EDC table 124.

The EDC table 124 may be configured as described above. Each block of data that is stored and retrieved may have a fixed size. In one example of an EDC table 124, the number of rows or records in the EDC table 124 may equal the number of bits in the block of data. Each record may contain an EDC result calculated from an input string of all zeros with one bit flipped, and the flipped bit may correspond with the record. For example, an EDC table may contain a first record for a string with only the first bit flipped, the second record for a string with only the second bit flipped, and so forth. Each record may contain the EDC result for the particular string.

When a checksum or EDC result is calculated from a block of data and the EDC result is not the default value, the EDC result may be attempted to be located in the EDC table 124. If the EDC result is found in the EDC table 124, the bit corresponding to the record within the EDC table 124 matching the EDC result is the incorrect bit. The incorrect bit may be flipped and the data may be used.

If the search of the EDC table 124 is not successful, each record in the EDC may be evaluated by taking an XOR of the record's EDC value and the EDC results for the data, then searching for the resultant value in the EDC table 124. If a result is found, two bits may be incorrect: the bit represented by the first record's EDC value and the bit represented by the second record's EDC value. A similar process may be used for determining three, four, or more incorrect bits.

The EDC table 124 may be calculated ahead of time and stored for rapid access. In some embodiments, the EDC table 124 may be calculated on the fly. Other embodiments may embed the EDC table 124 in code or may store the EDC table 124 as a separate file.

In many embodiments, the EDC table 124 may be known when creating the embodiment. The EDC table 124 is a function of the number of bits in a block of data, as well as the specific EDC function. For example, many disk storage systems may store data in 512 or 520 byte units. In other embodiments, the data block size may be determined during configuration of the system or may be changed over time. In such cases, an EDC table 124 may be created during an installation sequence or when the data block size changes.

The general method for adding an EDC result to data, then using the EDC function and an EDC table to identify and correct data errors may be used in any system where data is stored and retrieved. Another embodiment may be used in communication systems, as described in embodiment 200.

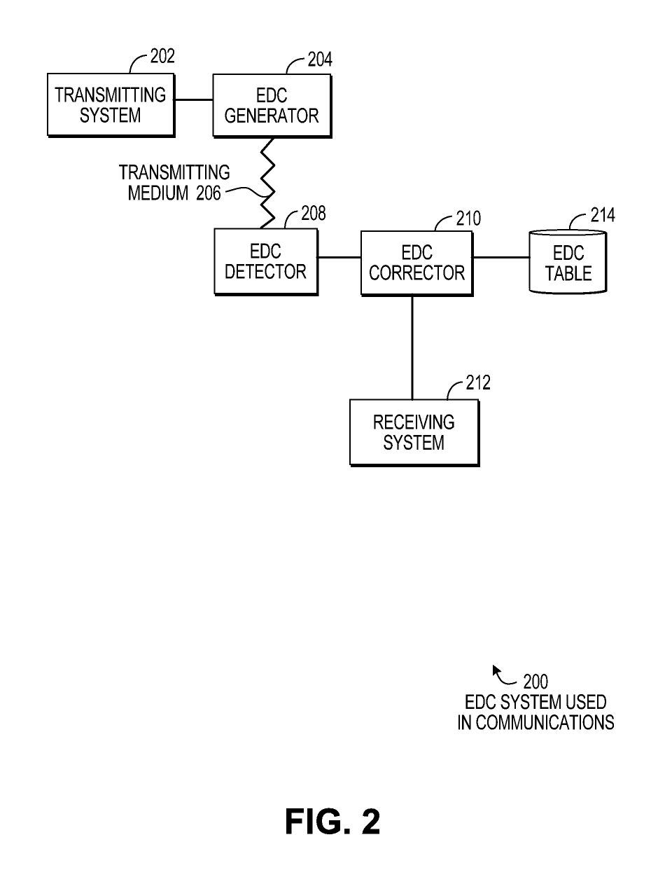

FIG. 2 is a diagram of an embodiment 200 showing a communications system that may be use Error Detection Codes (EDC) for both error detection and error correction. Embodiment 200 is a simplified example of an example of such a system that may be used in a generalized communication system.

The diagram of FIG. 2 illustrates functional components of a system. In some cases, the component may be a hardware component, a software component, or a combination of hardware and software. Some of the components may be application level software, while other components may be operating system level components. In some cases, the connection of one component to another may be a close connection where two or more components are operating on a single hardware platform. In other cases, the connections may be made over network connections spanning long distances. Each embodiment may use different hardware, software, and interconnection architectures to achieve the functions described.

Embodiment 200 is a simplified example of a communications system. A transmitting system 202 may send data to an EDC generator 204 that may compute a checksum or EDC result and append the EDC result to the data. The data with the appended EDC result may be transmitted over a transmitting medium 206.

An EDC detector 208 may process the incoming data using the EDC function. If the EDC result is not the default value, an EDC corrector 210 may use an EDC table 214 to attempt to correct the data. If the data block is correctable, or if the data block was correctly received, the data may be passed to a receiving system 212 that may use the data.

Embodiment 200 may be any type of communications system where one device communicates with another device. Examples include hardwired or wireless communication systems, or communication through networks that may be prone to occasional data loss.

Embodiment 200 illustrates the communication from a transmitting system 202 to a receiving system 212. In many embodiments, two way communication may be performed when each device is outfitted with an EDC generator as well as an EDC detector and EDC corrector. In some such embodiments, full duplex communication may be achieved.

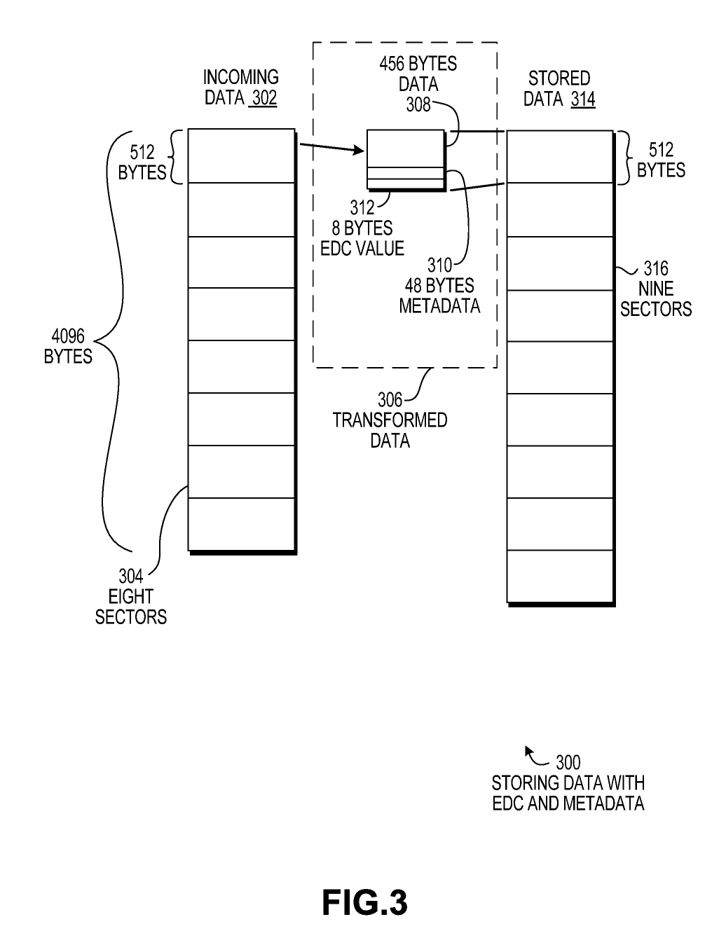

FIG. 3 is a diagram illustration of an embodiment 300 showing how incoming data may be transformed and stored in some cases. Embodiment 300 is an example of how incoming data 302 may be transformed and stored. Similar embodiments may be used for embodiments where data are transmitted. Because the EDC process adds a checksum or EDC result to the data, the stored or transmitted data is larger than the original data.

Embodiment 300 is an example of data that may be stored using a file storage system and stored using conventional disk drives. The incoming data 302 may consist of eight sectors 304, each sector may contain 512 bytes of data, and a block of data may contain a total of 4096 bytes. The 4096 byte block size may be used in many conventional disk operating systems for the unit of storage managed by a file management system. In many cases, disk storage systems store data in 512 byte sectors.

In order to store the incoming data 302 with a checksum or EDC result, the stored data 314 comprises nine sectors 316. Each sector in the stored data 314 is 512 bytes in size, corresponding to a standard size for data on a hard disk drive.

The sectors of data are changed into transformed data 306. A transformed sector may include 456 bytes of data 308, 48 bytes of metadata 310, and 8 bytes of an EDC value 312. The EDC value 312 is calculated so that when the EDC function is performed on the entire sector of transformed data 306, the EDC function will return a default value.

Embodiment 300 illustrates one method of storing eight sectors of data on nine sectors of storage space. Each sector may include data 308, metadata 310, and an EDC value 312. The 456 byte size for the data 308 may be determined by multiplying the incoming sector size of 512 by 8/9.

The EDC value 312 may be determined using any function that meets the properties defined above for an appropriate EDC function. In the case of 512 byte blocks of data, one such EDC function may be CRC-64-ISO which may use the polynomial

x⁶⁴+x⁴+x³+x+1

and may generate an 8 byte result. Other EDC functions may also be used.

The metadata 310 may be used to store any information about the data. In some embodiments, the metadata may be used by a storage manager to identify how the sector is to be stored among various storage devices, for example. In cases where the metadata 310 are not used, the metadata 310 may be set to a default value, such as all zeros.

Embodiment 300 is an example of using 512 byte sectors on a storage media to store 512 byte blocks of incoming data. In some embodiments, the incoming data may be 512 bytes, but the storage media may be formatted to store 520 byte sectors. In such embodiments, incoming data of 512 bytes may have 8 bytes of EDC results appended and may be stored in a 520 byte sector.

Embodiment 300 is described as a storage embodiment, such as embodiment 100. The same or similar configurations may be used for a communication embodiment, such as embodiment 200.

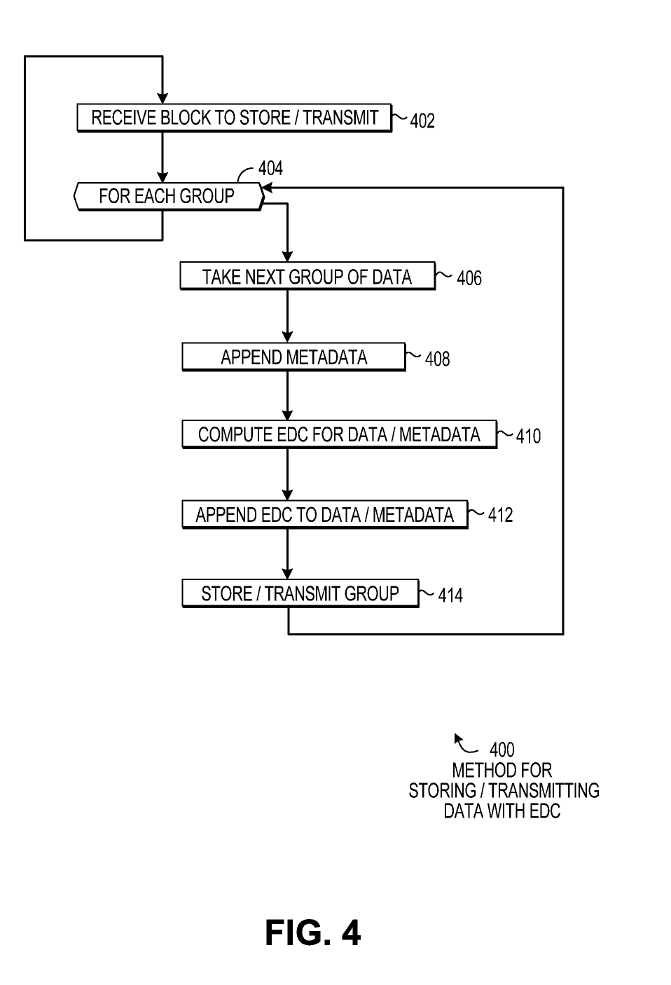

FIG. 4 is a flowchart illustration of an embodiment 400 showing a method for storing or transmitting data with an EDC result. Embodiment 400 is a simplified example of a method that may be performed by an EDC generator 118 or 204 as described in embodiments 100 or 200, respectively.

Other embodiments may use different sequencing, additional or fewer steps, and different nomenclature or terminology to accomplish similar functions. In some embodiments, various operations or set of operations may be performed in parallel with other operations, either in a synchronous or asynchronous manner. The steps selected here were chosen to illustrate some principles of operations in a simplified form.

Embodiment 400 is an example of a method for receiving data, breaking the data into blocks, and appending an EDC result to the block. Embodiment 400 uses a standard size block for storing or transmitting data. A standard size block may allow an EDC detector and EDC corrector to detect and correct data using an EDC table as described above and in embodiment 500 described below.

Embodiment 400 may process data using a first in, first out buffer. Data may be received in order and processed by taking data from the buffer in blocks, processing the block, and transmitting the block.

In block 402, a block of data to store or transmit may be received. In some cases, the block of received data may be a continuous stream of data. In many cases, the received data may be organized into blocks of data, such as multiples of the incoming block of data 302 that comprised eight sectors 304 as described in embodiment 300.

In block 404, each group of data may be processed. In block 406, the next group of data may be identified. In the case of embodiment 300, an incoming block of data may be processed by pulling 456 bytes of data from the data to process. In other embodiments, blocks of data that are 512 bytes or some other size may be pulled from the incoming data.

In block 408, metadata may be appended to the data. The metadata may be any metadata or additional data that may be stored or transmitted with the data. In some embodiments, the metadata may be used by a storage system or communication system in processing the data, for example. Some embodiments may not append metadata and may omit block 408.

The EDC may be computed for the data and metadata in block 410. In many embodiments, the EDC result or checksum may be computed such that performing the EDC function over the combined data/metadata/EDC result will yield a default value. A typical default value may be zero.

The EDC result may be appended to the data/metadata in block 412. In a typical embodiment, the size of the combined data/metadata/EDC result may be a standard size block of data that corresponds to a block of data handled by a communication protocol or by a storage media. In the case of a disk storage system, for example, a standard size sector may be 512 bytes or 520 bytes. Other storage systems or communication systems may use a different data block size.

The group of data may be stored or transmitted in block 414. The method may return to block 404 to process additional groups of data. After all the groups of data are processed, the method may return to block 402 to receive additional data blocks.

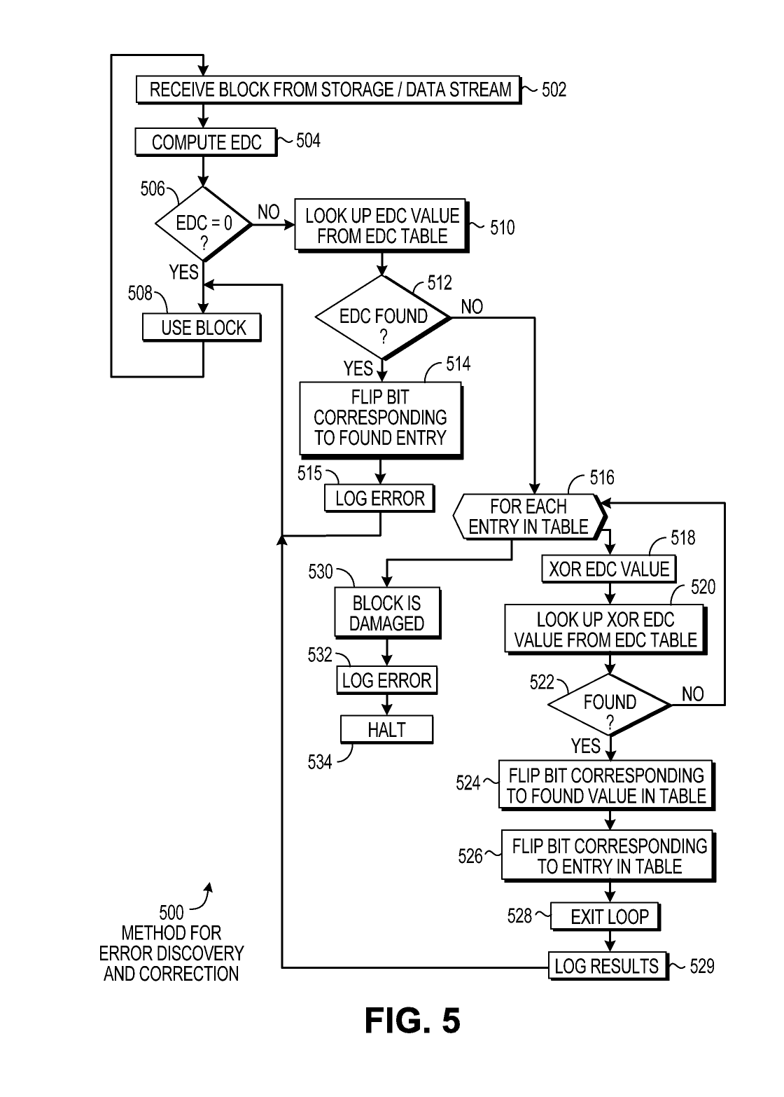

FIG. 5 is a flowchart illustration of an embodiment 500 showing a method for error discovery and correction for data blocks that may be created from embodiment 400. Embodiment 500 is a simplified example of a method for correcting single bit or double bit errors in blocks of data.

Other embodiments may use different sequencing, additional or fewer steps, and different nomenclature or terminology to accomplish similar functions. In some embodiments, various operations or set of operations may be performed in parallel with other operations, either in a synchronous or asynchronous manner. The steps selected here were chosen to illustrate some principles of operations in a simplified form.

Embodiment 500 is an example of a method for using error detection codes as an error correction mechanism. The method uses the EDC results to identify one or two bits that may be incorrect in the data.

In many systems, the reliability of stored or transmitted data may be quite high. In a typical disk based storage system, incorrect bits may occur as infrequently as one bit in many gigabytes or even terabytes of data. However, as a disk drive or other storage medium begins to fail, the error rates may rise dramatically. By capturing and logging the errors, the stability of the storage device or storage system may be monitored. If excessive errors are noted, an alert may be generated or data may be shifted to an alternative storage device.

In block 502, a data block may be received from a storage device or a transmitted data stream. In the example of embodiment 300, the data block may be a sector of data from a storage device. The data block received in block 502 may be the data block that contains an EDC result such that analyzing the data block with the EDC function will result in a default value when the data block is not corrupted.

The EDC result for the block may be computed in block 504. As described above, many different functions may be used to compute the EDC result. The EDC function is the same function as was used to create the appended EDC result in the block of data.

If the EDC result is a default value in block 506, the block of data may be used in block 508 and the process may return to block 502 to process another block of data. In many embodiments, the default value of the EDC result may be zero. Other embodiments may have other default values.

If the EDC result is not the default value in block 506, the EDC value may be looked up in the EDC table. If the EDC result is found in the EDC table in block 512, the EDC table record in which the EDC result is found may correspond to a specific bit that is incorrect.

In block 514, the incorrect bit may be flipped corresponding to the record in the EDC table. By flipping the incorrect bit, the data block may be corrected.

The error may be logged in block 515. Each embodiment may have different mechanisms for logging an error. In a storage system such as in embodiment 100, a logging operation may track an error may logging the storage device on which the data were stored. In some embodiments, the log record may include a sector identifier, bit identifier, or other identifiers that may identify the general location or specific location of the error.

In some embodiments, a notification system may track errors and produce alerts when errors indicate a potential problem. For example, hard disk drives and solid state storage devices may fail over repeated uses. The failure of a storage device may be predicted by an accumulation of errors from the storage device. In some embodiments, a sector or other area of the storage media that contains errors may be labeled as inoperative and prevented from further use.

In some embodiments with multiple storage devices, an accumulation of errors on one storage device may prompt a storage manager to move data from the error prone storage device to other devices with fewer errors.

If the EDC result is not found in block 512, two or more bits may be incorrect. When two bits are incorrect in the data, the EDC result may be an XOR of two EDC results corresponding to the two bits, as found in the EDC table. A searching method for finding two bits using the EDC table begins at block 516.

In block 516, each entry in the EDC table is evaluated.

In block 518, an XOR of the EDC result is performed with the current EDC value from the EDC table to produce an intermediate result. The intermediate result may be searched in the EDC table in block 520. If no matches are found in block 522, the process may return to block 516 to analyze another entry in the EDC table.

If the intermediate result is found in the EDC table in block 522, the two bits that are incorrect may be identified. The first bit may be the bit corresponding to the intermediate result as found in block 520, and the second bit may be the bit corresponding to the table entry being analyzed in block 516.

In block 524, the bit corresponding to the intermediate result may be flipped, and in block 526, the bit corresponding to the entry being analyzed in block 516 may also be flipped.

Since both bits have been corrected, the loop of block 516 may be exited in block 528 and the results may be logged in block 529.

If the loop of block 516 processes every record of the EDC table without finding a match, more than two bits may be damaged. In some embodiments, a third bit may be searched using a similar analysis of blocks 516 through 529 but applied to three values of the EDC table.

In embodiment 500, if more than two bits are incorrect, the block may be considered damaged in block 530. The error may be logged in block 532 and the process may be halted in block 534 or some other remedy may be performed.

The foregoing description of the subject matter has been presented for purposes of illustration and description. It is not intended to be exhaustive or to limit the subject matter to the precise form disclosed, and other modifications and variations may be possible in light of the above teachings. The embodiment was chosen and described in order to best explain the principles of the invention and its practical application to thereby enable others skilled in the art to best utilize the invention in various embodiments and various modifications as are suited to the particular use contemplated. It is intended that the appended claims be construed to include other alternative embodiments except insofar as limited by the prior art.

What is claimed is:

1. A method comprising:
reading a block of information, said block of information comprising data and an EDC function result, said EDC function result being configured such that an EDC function performed on said block of information in an original state may return a default value, said block of information being comprised in a first number of bits;
performing said EDC function on said block of information and receiving a first value;
determining that said first value is not said default value;
looking up said first result in an EDC result table, said EDC result table comprising results for said EDC function performed on a set of bits having a size of said first number of bits, said set of bits having said default value with one of said bits being flipped;
finding a match from said EDC result table and identifying a first flipped bit from said EDC result table; and
flipping said first flipped bit in said block of information to return said block of information to said original state.

2. The method of claim 1, said EDC function being a CRC function.

3. The method of claim 2, said CRC function being a CRC-64 function.

4. The method of claim 1, said block of information being read from a storage device.

5. The method of claim 1, said block of information being read from a stream of information being transmitted over a network.

6. The method of claim 1, said default value is zero.

7. The method of claim 1, said block of information further comprising metadata about said data.

8. A system comprising:
a set of storage devices on which information may be stored;
a storage controller configured to store data using a storage method comprising:
receiving a block of data;
creating a first storage block comprising at least a portion of said block of data and an EDC function result, said EDD function result being determined such that performing an EDC function on said first storage block results in a default value, said first storage block composed of a first number of bits; and
storing said first storage block on said set of storage devices;
said storage controller configured to retrieve data using a retrieval method comprising:
retrieving a second storage block from said set of storage devices, said second storage block being a corrupted version of said first storage block;
performing said EDC function on said second storage block to obtain an EDC result;
determining a flipped bit in said second storage block by analyzing said EDC results;
flipping said flipped bit in said second storage block to change said second storage block to said first storage block; and
using said data from said first storage block.

9. The system of claim 8, said analyzing said EDC results being performed by a method comprising:
looking up said EDC result in a table comprising EDC results for a block of data composed of said default value and having said first number of bits, each entry in said table comprising an EDC function result for said block of data having one bit flipped; and
finding a match from said EDC result table and identifying a first flipped bit from said EDC result table.

10. The system of claim 9, said system being comprised in a disk controller peripheral.

11. The system of claim 9, said storage controller being at least partially implemented in an operating system level component.

12. The system of claim 9, said storage controller being at least partially implemented in an application.

13. The system of claim 8, said set of storage devices being configured in a RAID configuration.

14. The system of claim 8, said set of storage devices composed of a single storage device.

15. The system of claim 8, said block of data being grouped in 512 byte groups and said first storage block composed of 520 bytes.

16. The system of claim 8, said block of data being grouped in 4096 byte groups composed of 512 byte subgroups, and said first storage block comprising 512 bytes, wherein nine of storage blocks are used to store said block of data.

17. The system of claim 16, said first storage block comprising at least 450 bytes of said block of data.

18. The system of claim 8 further comprising:
a logging system configured to:
identify a correction action taken by said storage controller and a storage device from which said block of data is retrieved; and
log said correction action and said storage device in a log.

19. A method comprising:
reading a block of information, said block of information comprising data and a CRC function result, said CRC function result being configured such that an CRC function on said block of information in an original state may return a default value, said block of information being comprised in a first number of bits;
performing said CRC function on said block of information and receiving a first value;
determining that said first value is not said default value;
creating a CRC result table by a process comprising:
for each of said first number of bits, flipping a corresponding bit in said default value to create a sample data block;
calculating said CRC function for said sample data block to create a CRC result corresponding to said corresponding bit; and
storing said CRC result in said CRC result table;
looking up said first result in a CRC result table;
finding a match from said EDC result table and identifying a first flipped bit from said EDC result table; and
flipping said first flipped bit in said block of information to return said block of information to said original state.

20. The method of claim 19, said creating a CRC result table being performed prior to said reading a block of information.
